(19) United States
(12) Patent Application Publication
(10) Pub. No.: US 2020/0075297 A1
(43) Pub. Date: Mar. 5, 2020

(54) EXHAUST PIPE DEVICE AND CLEANING DEVICE

(71) Applicant: Toshiba Memory Corporation, Tokyo (JP)

(72) Inventors: Akihiro OISHI, Yokohama (JP); Hiroyuki FUKUMIZU, Yokohama (JP); Hiroshi MATSUBA, Fujisawa (JP); Kazuaki KURIHARA, Yokohama (JP); Takeshi YAMAUCHI, Yokohama (JP)

(73) Assignee: Toshiba Memory Corporation, Tokyo (JP)

(21) Appl. No.: 16/292,260

(22) Filed: Mar. 4, 2019

(30) Foreign Application Priority Data
Aug. 30, 2018 (JP) 2018-162190

(51) Int. Cl. H01J 37/32; H01L 21/67; C23C 16/44; B08B 5/02; B08B 7/00; B08B 9/032

(52) U.S. Cl. CPC H01J 37/32834; H01L 21/67017; H01J 37/32568; H01J 37/32082; H01J 37/32541; B08B 2209/027; B08B 5/02; B08B 7/0071; B08B 9/0328; H01J 2237/335; H01J 2237/002; C23C 16/4405

(57) ABSTRACT

An exhaust pipe device according to an embodiment includes a pipe body; an internal electrode disposed in the pipe body; and a plasma generation circuit configured to generate plasma in the pipe body by using the internal electrode, wherein the exhaust pipe device is used as a part of an exhaust pipe disposed between a film forming chamber and a vacuum pump for exhausting an inside of the film forming chamber.

### CROSS-REFERENCE TO RELATED APPLICATION

This application is based upon and claims the benefit of priority from Japanese Patent Application No. 2018-162190 filed on Aug. 30, 2018 in Japan, the entire contents of which are incorporated herein by reference.

### FIELD

Embodiments described herein relate generally to an exhaust pipe device and a cleaning device.

### BACKGROUND

In a film forming device represented by a chemical vapor deposition (CVD) device, raw material gas is introduced into a film forming chamber and a desired film is formed on a substrate disposed in the film forming chamber. The raw material gas remaining in the film forming chamber is exhausted by a vacuum pump via an exhaust pipe. At that time, products resulting from the raw material gas may be deposited in the exhaust pipe to close the exhaust pipe or the products may be deposited in the vacuum pump on the downstream side of the exhaust pipe to stop the vacuum pump. To remove the deposited products, cleaning processing is performed by a remote plasma source (RPS) device. However, since the RPS device generally focuses on cleaning in the film forming chamber, cleaning performance is insufficient to clean the products deposited in the exhaust pipe of the vicinity of the vacuum pump distant from the RPS device and the vacuum pump.

### BRIEF DESCRIPTION OF THE DRAWINGS

FIG. 1 is a configuration diagram showing an example of a configuration of an exhaust system of a semiconductor manufacturing device in a first embodiment;

FIG. 2 is a cross-sectional view of an example of an exhaust pipe device in the first embodiment when viewed from a front direction;

FIG. 3 is a cross-sectional view of an example of the exhaust pipe device in the first embodiment when viewed from a top surface direction;

FIGS. 4A and 4B are diagrams showing an example of a configuration of an introduction terminal port in the first embodiment;

FIG. 5 is a cross-sectional view of an example of an exhaust pipe device in a second embodiment when viewed from a front direction;

FIG. 6 is a cross-sectional view of an example of the exhaust pipe device in the second embodiment when viewed from a top surface direction;

FIG. 7 is a cross-sectional view of an example of an exhaust pipe device in a third embodiment when viewed from a front direction;

FIG. 8 is a cross-sectional view of an example of the exhaust pipe device in the third embodiment when viewed from a top surface direction;

FIG. 9 is a cross-sectional view of an example of an exhaust pipe device in a fourth embodiment when viewed from a front direction;

FIG. 10 is a cross-sectional view of an example of the exhaust pipe device in the fourth embodiment when viewed from a top surface direction;

FIG. 11 is a cross-sectional view of an example of an exhaust pipe device in a fifth embodiment when viewed from a front direction;

FIG. 12 is a cross-sectional view of an example of the exhaust pipe device in the fifth embodiment when viewed from a top surface direction;

FIG. 13 is a cross-sectional view of an example of an exhaust pipe device in a sixth embodiment when viewed from a front direction;

FIG. 14 is a time chart showing an example of a film forming process sequence in the sixth embodiment;

FIG. 15 is a cross-sectional view of an example of an exhaust pipe device in a seventh embodiment when viewed from a front direction;

FIG. 16 is a cross-sectional view of an example of an exhaust pipe device in an eighth embodiment when viewed from a front direction;

FIG. 17 is a diagram showing an example of a relation between a cleaning rate and a discharge pressure in the eighth embodiment;

FIG. 18 is a cross-sectional view of an example of an exhaust pipe device in a ninth embodiment when viewed from a front direction;

FIG. 19 is a cross-sectional view of an example of an exhaust pipe device in a tenth embodiment when viewed from a front direction;

FIG. 20 is a cross-sectional view of an example of an exhaust pipe device in an eleventh embodiment when viewed from a front direction;

FIG. 21 is a cross-sectional view of an example of an exhaust pipe device in a twelfth embodiment when viewed from a front direction;

FIG. 22 is a cross-sectional view of an example of an exhaust pipe device in a thirteenth embodiment when viewed from a front direction; and

FIG. 23 is a cross-sectional view of an example of an exhaust pipe device in a fourteenth embodiment when viewed from a front direction.

### DETAILED DESCRIPTION

An exhaust pipe device according to an embodiment includes a pipe body, an internal electrode and a plasma generation circuit. The internal electrode is disposed in the pipe body. The plasma generation circuit is configured to generate plasma in the pipe body by using the internal electrode. The exhaust pipe device is used as a part of an exhaust pipe disposed between a film forming chamber and a vacuum pump for exhausting an inside of the film forming chamber.

In the following embodiments, an exhaust pipe device and/or a cleaning device capable of removing products deposited in an exhaust pipe near a vacuum pump will be described.

### First Embodiment

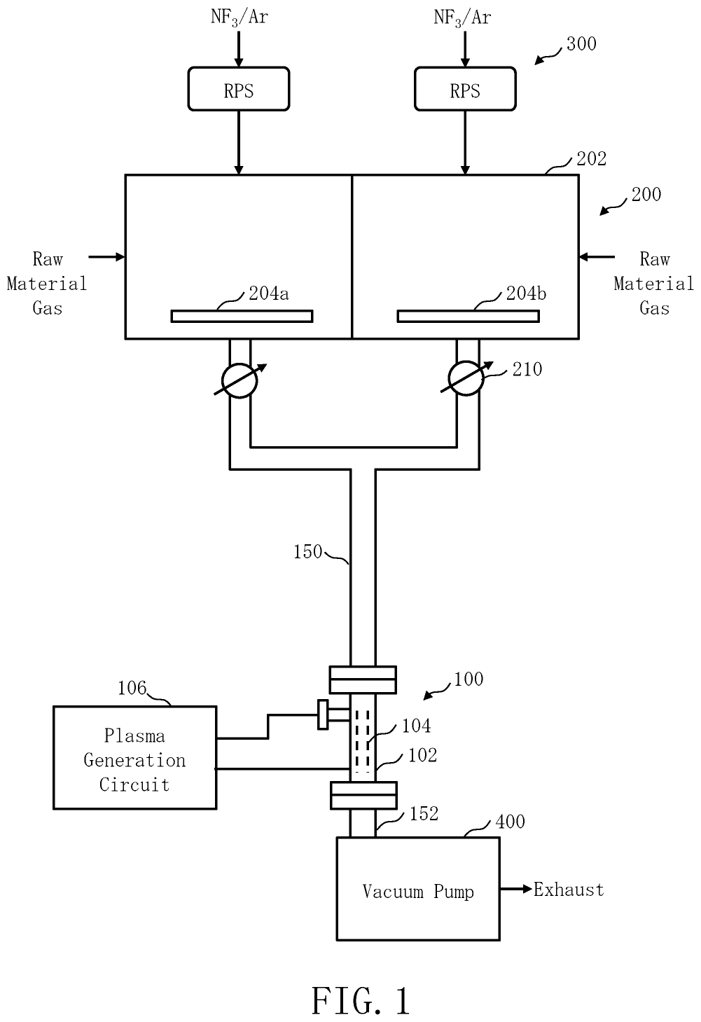

FIG. 1 is a configuration diagram showing an example of a configuration of an exhaust system of a semiconductor manufacturing device in a first embodiment; In the example of FIG. 1, a film forming device, for example, a chemical vapor deposition (CVD) device 200 is shown as the semiconductor manufacturing device. In the example of FIG. 1, a multi-chamber type CVD device 200 in which two film forming chambers 202 are disposed is shown. In the CVD device 200, semiconductor substrates 204 (204a and 204b) to be film-formed are disposed in the film forming chambers 202 controlled to a desired temperature. In addition, evacuation is performed through exhaust pipes 150 and 152 by a vacuum pump 400 and raw material gas is supplied to the inside of the film forming chamber 202 controlled to a desired pressure by a pressure control valve 210. In the film forming chamber 202, a desired film is formed on the substrate 204 by a chemical reaction of the raw material gas. For example, a silicon oxide film (SiO film) or a silicon nitride film (SiN film) is formed by introducing silane (SiH₄) gas as main raw material gas. In addition, for example, tetraethoxysilane (TEOS) gas or the like is introduced as main raw material gas to form a silicon oxide film (SiO film). When these films are formed, products resulting from the raw material gas are deposited in the film forming chamber 202 and the exhaust pipes 150 and 152. Therefore, in a film forming process cycle, a cleaning step is performed in addition to a film forming step. In the cleaning step, cleaning gas such as nitrogen trifluoride (NF₃) gas or purge gas such as argon (Ar) gas is supplied to remote plasma source (RPS) devices 300 disposed on the upstream side of the film forming chambers 202 and fluorine (F) radicals are generated by plasma. Then, by supplying (diffusing) the F radicals to the inside of the film forming chamber 202 and the side of the exhaust pipe 150, cleaning of the products to be deposited is performed. For example, silicon tetrafluoride (SiF₄) generated after decomposition of the deposited products by cleaning is highly volatile, so that it is discharged from the vacuum pump 400 through the exhaust pipes 150 and 152.

However, it may be difficult for the F radicals to reach portions of the exhaust pipes 150 and 152 distant from the film forming chamber 202 and cleaning performance may be degraded. In particular, because a pressure is lowered at a position close to a suction port of the vacuum pump 400, a cleaning rate may be lowered. As a result, the exhaust pipes 150 and 152 may be closed by the deposited products. In addition, a gap between a rotor and a casing may be filled with the products deposited in the vacuum pump 400 to thereby enter an overload state and the vacuum pump 400 may be stopped. Therefore, in the first embodiment, as shown in FIG. 1, an exhaust pipe device 100 is disposed at a position closer to the suction port of the vacuum pump 400 than the film forming chamber 202.

In FIG. 1, the exhaust pipe device 100 according to the first embodiment is used as a part of an exhaust pipe including the exhaust pipes 150 and 152 disposed between the film forming chamber 202 and the vacuum pump 400 for exhausting or “evacuating” an inside of the film forming chamber 202. The exhaust pipe device 100 includes a pipe body 102, internal electrodes 104, and a plasma generation circuit 106. For the pipe body 102, for example, a pipe material made of the same material as those of the normal exhaust pipes 150 and 152 is used. For example, a stainless steel material such as SUS304 is used. However, from the viewpoint of corrosion resistance against the cleaning gas, an SUS316 steel material is more preferably used as the material of the pipe body 102. Further, for the pipe body 102, for example, a pipe material having the same size as those of the normal exhaust pipes 150 and 152 is used. However, the present disclosure is not limited thereto. For the pipe body 102, a pipe having a size larger than those of the exhaust pipes 150 and 152 may be used. Alternatively, for the pipe body 102, a pipe having a size smaller than those of the exhaust pipes 150 and 152 may be used. Flanges are disposed at both ends of the pipe body 102, one end of the pipe body 102 is connected to the exhaust pipe 150 on which a flange having the same size is disposed, and the other end thereof is connected to the exhaust pipe 152 on which a flange having the same size is disposed. In FIG. 1, illustration of a clamp or the like for fixing the flange of the exhaust pipe device 100 and the respective flanges of the exhaust pipes 150 and 152 is omitted. Hereinafter, the same is applied to the respective drawings. In each of the embodiments to be described below, the case where the exhaust pipe 152 is interposed between the exhaust pipe device 100 and the vacuum pump 400 is shown. However, the present disclosure is not limited thereto. The exhaust pipe device 100 may be disposed directly at the suction port of the vacuum pump 400. The internal electrodes 104 are disposed in the pipe body 102. The plasma generation circuit 106 uses the internal electrodes 104 to generate plasma in the pipe body 102.

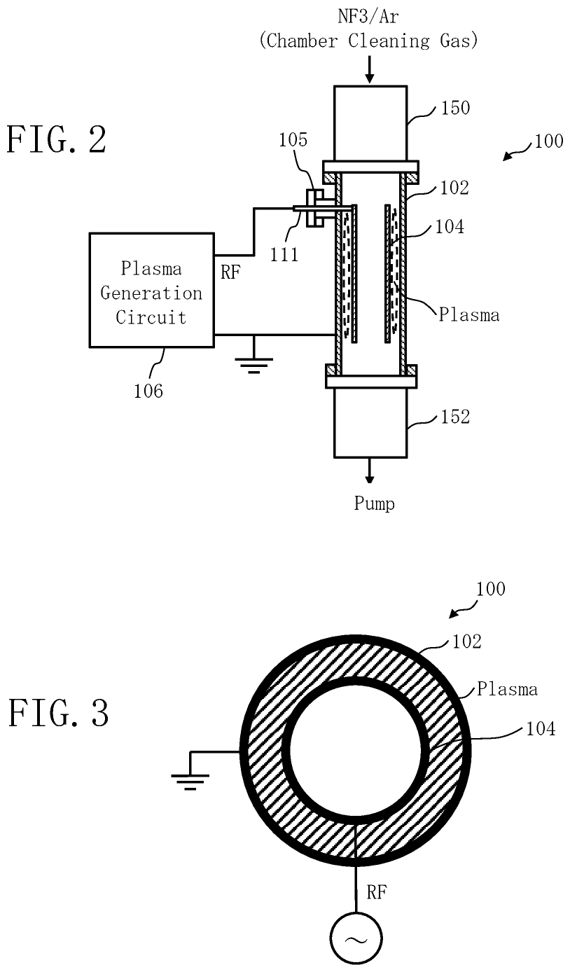

FIG. 2 is a cross-sectional view of an example of an exhaust pipe device in the first embodiment when viewed from a front direction. FIG. 3 is a cross-sectional view of an example of the exhaust pipe device in the first embodiment when viewed from a top surface direction. In FIG. 2, a cross-sectional structure shows the exhaust pipe device 100 and the rest of the structure does not show a cross-section. Hereinafter, the same is applied to each cross-sectional view viewed from the front direction. In FIG. 2, a metal electrode is used as the internal electrode 104. For example, a stainless steel material is used. A material of the internal electrode 104 may be the same material as those of the exhaust pipes 150 and 152. However, similar to the pipe body 102, an SUS316 material is preferable from the viewpoint of corrosion resistance against the cleaning gas or the like. As the material of the internal electrode 104, aluminum (Al) may also be used. From the viewpoint of corrosion resistance against the cleaning gas or the like, an inner wall surface of the pipe body 102 and/or a surface of the internal electrode 104 is preferably coated with a ceramic material. For example, alumina (Al₂O₃), yttria (Y₂O₃), hafnia (HfO₂), zirconia (ZrO₂), magnesium oxide (MgO), or aluminum nitride (AlN) is preferably used as the ceramic material. The internal electrode 104 is formed in a hollow structure (cylindrical shape). By taking the hollow structure, it is possible to reduce a decrease in conductance and to reduce an influence on exhaust performance. The internal electrode 104 is formed in the same type of shape as that of the pipe body 102. In the example of FIG. 3, for the pipe body 102 having a circular cross-section, the internal electrode 104 having the same type of circular cross-section is used. In addition, for the pipe body 102 having a rectangular cross-section, the internal electrode 104 having the same type of rectangular cross-section may be used. By taking the same type of cross-sectional shape, in other words, a similar shape, it is possible to cause a distance of a space between the pipe body 102 and the internal electrode 104 to be substantially constant or to be constant.

In the examples of FIGS. 2 and 3, the case where a radio-frequency (RF) voltage is applied to the internal electrode 104 with the pipe body 102 as a ground electrode connected to a ground is shown. Specifically, an introduction terminal 111 (an example of a radio-frequency introduction terminal) is introduced into the pipe body 102 from an introduction terminal port 105 connected to an outer circumferential surface of the pipe body 102 and the introduction terminal 111 is connected to the internal electrode 104. In FIG. 2, illustration of the introduction terminal port 105 is shown in a simplified manner. Hereinafter, the same is applied to the respective drawings, except for an enlarged view showing the details of the introduction terminal port 105. The plasma generation circuit 106 applies a radio-frequency (RF) voltage to the internal electrode 104 via the introduction terminal 111 with the pipe body 102 as the ground electrode connected to the ground, thereby applying the radio-frequency electric field between the internal electrode 104 and the pipe body 102 (ground electrode). As a result, the plasma (capacitively coupled plasma: CCP) is generated in the space between the internal electrode 104 and the pipe body 102. Since the distance of the space between the pipe body 102 and the internal electrode 104 is substantially constant, a stable plasma space can be generated. The F radicals based on the plasma are generated by using the rest of the cleaning gas such as NF₃ gas supplied from the upstream side by the cleaning step described above. Then, the products deposited in the pipe body 102 are removed by the F radicals. As a result, high cleaning performance can be exerted in the exhaust pipe 152. For example, SiF₄ generated after decomposition of the deposited products by the F radicals is highly volatile, so that it is discharged by the vacuum pump 400 through the exhaust pipe 152. In addition, a part of the radicals generated by the exhaust pipe device 100 cleans the products deposited in the vacuum pump 400, so that it is possible to reduce an amount of products deposited in the vacuum pump 400.

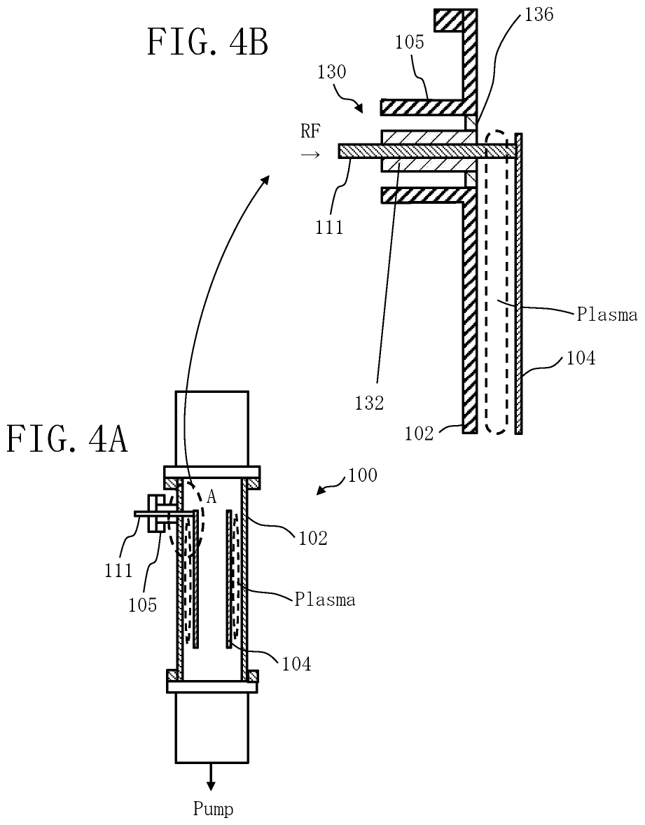

FIGS. 4A and 4B are diagrams showing an example of a configuration of an introduction terminal port in the first embodiment; An enlarged view showing the details of an A portion of FIG. 4A is shown in FIG. 4B. In FIG. 4B, the introduction terminal port 105 is connected to the outer circumferential surface of the pipe body 102. On the other hand, an introduction terminal unit 130 is inserted and fixed into the pipe body 102 from the introduction terminal port 105, in a state where an entire outer circumferential surface of the introduction terminal 111 is surrounded by an insulator 132 made of an insulating material. In a state where the introduction terminal unit 130 is fixed to the introduction terminal port 105, an end of the insulator 132 surrounding the introduction terminal 111 is formed to have a length extending to the vicinity of the inner wall surface of the pipe body 102. Therefore, in a state where the introduction terminal unit 130 is fixed to the introduction terminal port 105, the insulator 132 is disposed in the introduction terminal port 105 and surrounds the entire outer circumferential surface of the introduction terminal 111 in the introduction terminal port 105. The introduction terminal 111 is surrounded by the insulator 132, so that it is possible to prevent the discharge in the introduction terminal port 105 and the introduction terminal unit 130.

Here, since the pipe body 102 is exhausted by the vacuum pump 400, the radicals in the plasma are also flown in an exhaust direction (downstream side) by the vacuum pump 400. Therefore, if a disposition position of the introduction terminal 111 becomes closer to the downstream side, a part of the radicals generated on the upstream side of the disposition position of the introduction terminal 111 may leak into the side of the introduction terminal port 105 at an introduction position of the introduction terminal 111 and cleaning efficiency may be lowered. Therefore, as shown in FIG. 4B, the introduction terminal 111 is preferably connected to the vicinity of the upstream-side end of the internal electrode 104 located at the side of the film forming chamber 202 in the internal electrode 104. In other words, preferably, the introduction terminal 111 is inserted into the pipe body 102 at a position as close as possible to a front end of the internal electrode 104 and is connected to a position as close as possible to the front end of the internal electrode 104. By this configuration, an amount of radicals leaking into the introduction terminal port 105 can be suppressed.

Further, in the first embodiment, as shown in FIG. 4B, a spacer 136 is disposed in the introduction terminal port 105. The spacer 136 closes a gap between the insulator 132 and the inner wall of the introduction terminal port 105. As a result, it is possible to suppress or reduce leakage of the radicals in the plasma into the introduction terminal port 105. The spacer 136 is formed so that an end is located on substantially the same surface as the inner wall surface of the pipe body 102 and a surface facing the internal electrode 104 is flat continuous with the inner wall surface of the pipe body 102. The spacer 136 is preferably formed of a metal material. Since the spacer 136 is formed of the metal material and contacts the pipe body 102 (introduction terminal port 105) to be connected to the ground, the spacer 136 also becomes a ground electrode and exists at substantially the same distance as the pipe body 102 from the internal electrode 104. Therefore, the spacer 136 can generate the same plasma as that in the pipe body 102 between the internal electrode 104 and the spacer 136. Further, a small hole may be formed in the spacer 136 to the extent that hollow cathode discharge does not occur and the introduction terminal port 105 may be exhausted by the vacuum pump 400. If the small hole is formed to the extent that the hollow cathode discharge does not occur, it is possible to avoid substantially increasing the amount of radicals leaking into the introduction terminal port 105. However, the present disclosure is not limited thereto. The case where the spacer 136 is formed of an insulating material is not excluded.

As described above, according to the first embodiment, it is possible to remove the products deposited in the exhaust pipe 152 of the vicinity of the vacuum pump 400 distant from the film forming chamber 202. In addition, the products deposited in the vacuum pump 400 can be reduced. In addition, it is possible to reduce an installation area of the device for removing the deposited products.

### Second Embodiment

In the first embodiment, the configuration where a radio frequency is applied to an internal electrode has been described. However, the present disclosure is not limited thereto. In a second embodiment, a configuration where an internal electrode is used as a ground electrode will be described. In addition, points not specifically described below are the same as those of the first embodiment.

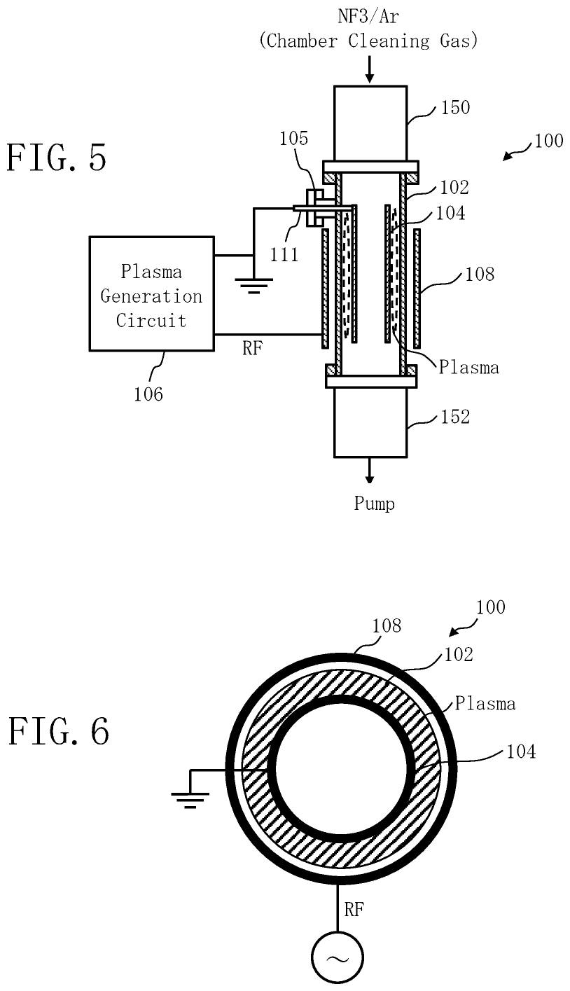

FIG. 5 is a cross-sectional view of an example of an exhaust pipe device in a second embodiment when viewed from a front direction. FIG. 6 is a cross-sectional view of an example of the exhaust pipe device in the second embodiment when viewed from a top surface direction. In FIG. 5, similar to the first embodiment, a metal electrode is used as an internal electrode 104. In FIGS. 5 and 6, in an exhaust pipe device 100 according to the second embodiment, an external electrode 108 is further disposed outside a pipe body 102. As shown in FIG. 6, the external electrode 108 is formed in the same type of shape as that of the pipe body 102. In the example of FIG. 6, for the pipe body 102 having a circular cross-section, the external electrode 108 having the same type of circular cross-section is used. In addition, for the pipe body 102 having a rectangular cross-section, the external electrode 108 having the same type of rectangular cross-section may be used. By taking the same type of cross-sectional shape, in other words, a similar shape, it is possible to cause a distance of a space between the pipe body 102 and the external electrode 108 to be substantially constant or to be constant. A material of the external electrode 108 may be the same material as those of exhaust pipes 150 and 152. Alternatively, the material of the external electrode 108 may be other conductive material. Since the external electrode 108 is disposed outside the pipe body 102, corrosion resistance may be lower than that of the internal electrode 104. The rest of the structure is identical to that of FIG. 2.

In the examples of FIGS. 5 and 6, the case where a radio-frequency (RF) voltage is applied to the external electrode 108 with the internal electrode 104 as a ground electrode connected to a ground is shown. Specifically, an introduction terminal 111 is introduced into the pipe body 102 from an introduction terminal port 105 connected to an outer circumferential surface of the pipe body 102 and the introduction terminal 111 is connected to the internal electrode 104. In addition, a plasma generation circuit 106 applies a radio-frequency (RF) voltage to the external electrode 108 with the internal electrode 104 as the ground electrode connected to the ground, thereby applying the radio-frequency electric field between the internal electrode 104 and the external electrode 108. As a result, the pipe body 102 functions as a discharge tube and generates plasma (capacitively coupled plasma: CCP) in a space between the internal electrode 104 and the pipe body 102. In order to cause the pipe body 102 to function as the discharge tube, for example, quartz, Al₂O₃, Y₂O₃, HfO₂, ZrO₂, MgO, or AlN is preferably used as the material of the pipe body 102 without using a metal material. Since a distance of the space between the pipe body 102 and the internal electrode 104 is substantially constant and a distance of a space between the pipe body 102 and the external electrode 108 is substantially constant, a stable plasma space can be generated. In the second embodiment, as compared with the case where inductively coupled plasma (ICP) is generated by winding a coil around the outer circumferential surface of the pipe body 102, a dielectric material for forming the discharge tube does not generate local scraping at a position facing the coil and the exhaust pipe device 100 can be operated over a long period. Similar to the first embodiment, F radicals based on the plasma are generated by using the rest of the cleaning gas such as NF₃ gas supplied from the upstream side by the cleaning step described above. Then, the products deposited in the pipe body 102 are removed by the F radicals. As a result, high cleaning performance can be exerted in the exhaust pipe 152. For example, SiF₄ generated after decomposition of the deposited products by the F radicals is highly volatile, so that it is discharged by the vacuum pump 400 through the exhaust pipe 152. In addition, a part of the radicals generated by the exhaust pipe device 100 cleans the products deposited in the vacuum pump 400, so that it is possible to reduce an amount of products deposited in the vacuum pump 400.

As described above, according to the second embodiment, even when the internal electrode 104 is used as the ground electrode, it is possible to remove the products deposited in the exhaust pipe 152 of the vicinity of the vacuum pump 400 distant from a film forming chamber 202. In addition, the products deposited in the vacuum pump 400 can be reduced.

### Third Embodiment

In the first and second embodiments, the case where plasma is generated in a space between an internal electrode 104 and a pipe body 102 has been described. However, the present disclosure is not limited thereto. In a third embodiment, a configuration for expanding a plasma space will be described. In addition, points not specifically described below are the same as those of the first embodiment.

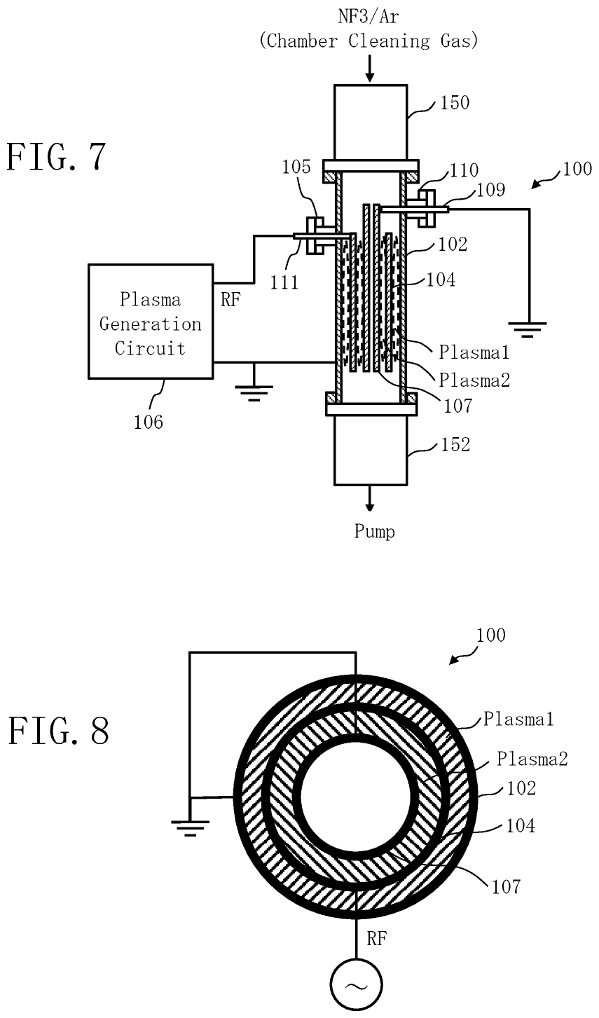

FIG. 7 is a cross-sectional view of an example of an exhaust pipe device in a third embodiment when viewed from a front direction. FIG. 8 is a cross-sectional view of an example of the exhaust pipe device in the third embodiment when viewed from a top surface direction. In FIGS. 7 and 8, in an exhaust pipe device 100 according to the third embodiment, another internal electrode 107 is further disposed inside the internal electrode 104. As shown in FIG. 8, the internal electrode 107 is formed in the same type of shape as that of the internal electrode 104. In the example of FIG. 8, for the internal electrode 104 having a circular cross-section, the internal electrode 107 having the same type of circular cross-section is used. In addition, for the internal electrode 104 having a rectangular cross-section, the internal electrodes 107 having the same type of rectangular cross-section may be used. By taking the same type of cross-sectional shape, in other words, a similar shape, it is possible to cause a distance of a space between the internal electrode 104 and the internal electrode 107 to be substantially constant or to be constant. A metal electrode is used as the internal electrode 107. For example, a stainless steel material is used. A material of the internal electrode 107 may be the same material as those of exhaust pipes 150 and 152. However, similar to the internal electrode 104, an SUS316 material is preferable from the viewpoint of corrosion resistance against cleaning gas or the like. As the material of the internal electrode 107, aluminum (Al) may also be used. From the viewpoint of corrosion resistance against the cleaning gas or the like, a surface of the internal electrode 107 is preferably coated with a ceramic material. As the ceramic material, for example, Al₂O₃, Y₂O₃, HfO₂, ZrO₂, MgO, or AlN is preferably used. The internal electrode 107 is preferably formed in a hollow structure (cylindrical shape). By taking the hollow structure, it is possible to reduce a decrease in conductance of the exhaust pipe and to reduce an influence on exhaust performance. An introduction terminal 109 is introduced into the pipe body 102 from an introduction terminal port 110 connected to an outer circumferential surface of the pipe body 102 and the introduction terminal 109 is connected to the internal electrode 107. In the example of FIG. 7, a front end position of the internal electrode 107 is set to the upstream side of a front end position of the internal electrode 104. The introduction terminal 109 is introduced from the introduction terminal port 110 disposed on the upstream side of an introduction terminal port 105 without interfering with the internal electrode 104 and is connected to the internal electrode 107. The rest of the structure is identical to that of FIG. 2.

In the examples of FIGS. 7 and 8, the case where a radio-frequency (RF) voltage is applied to the internal electrode 104 with the pipe body 102 as a ground electrode (first ground electrode) connected to a ground and the internal electrode 107 as a ground electrode (second ground electrode) connected to the ground is shown. Specifically, an introduction terminal 111 is introduced into the pipe body 102 from the introduction terminal port 105 and the introduction terminal 111 is connected to the internal electrode 104. Further, the introduction terminal 109 is introduced into the pipe body 102 from the introduction terminal port 110 and the introduction terminal 109 is connected to the internal electrode 107. In addition, the introduction terminal 109 is connected to the ground. A plasma generation circuit 106 applies a radio-frequency (RF) voltage to the internal electrode 104 via the introduction terminal 111 with both the pipe body 102 and the internal electrode 107 as the ground electrodes connected to the ground, thereby applying the radio-frequency electric field between the internal electrode 104 and the pipe body 102 (first ground electrode) and between the internal electrode 104 and the internal electrode 107 (second ground electrode). As a result, first plasma (capacitively coupled plasma: CCP) is generated in the space between the internal electrode 104 and the pipe body 102 and second plasma (CCP) is generated in the space between the internal electrode 104 and the internal electrode 107. As such, a plasma space can be expanded. Since the distance of the space between the pipe body 102 and the internal electrode 104 is substantially constant, a stable plasma space can be generated. Likewise, since a distance of the space between the internal electrode 104 and the internal electrode 107 is substantially constant, a stable plasma space can be generated. The F radicals based on the plasma are generated by using the rest of the cleaning gas such as NF₃ gas supplied from the upstream side by the cleaning step described above. Then, the products deposited in the pipe body 102 are removed by the F radicals. By expanding the plasma space, higher cleaning performance can be exerted in the exhaust pipe 152. For example, SiF₄ generated after decomposition of the deposited products by the F radicals is highly volatile, so that it is discharged by the vacuum pump 400 through the exhaust pipe 152. By expanding the plasma space, an amount of radicals diffusing into the vacuum pump 400 can also be increased. In addition, the products deposited in the vacuum pump 400 are cleaned by the radicals diffusing into the vacuum pump 400, so that it is possible to further reduce an amount of products deposited in the vacuum pump 400.

As described above, according to the third embodiment, the internal electrode 107 is further disposed, so that the plasma space can be expanded.

### Fourth Embodiment

In a fourth embodiment, a configuration for expanding a plasma space by a method different from that of the third embodiment will be described. In addition, points not specifically described below are the same as those of the first embodiment.

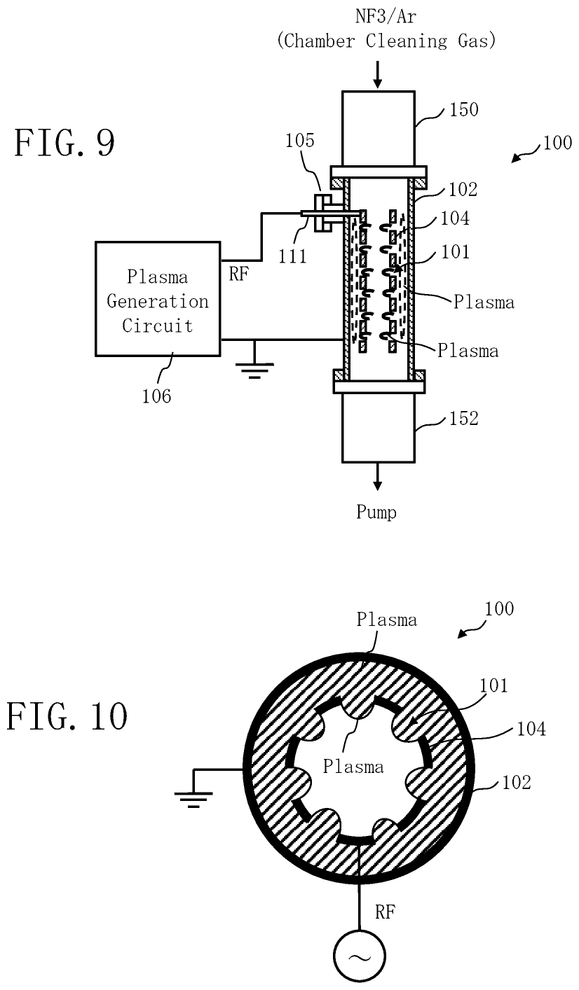

FIG. 9 is a cross-sectional view of an example of an exhaust pipe device in a fourth embodiment when viewed from a front direction. FIG. 10 is a cross-sectional view of an example of the exhaust pipe device in the fourth embodiment when viewed from a top surface direction. In FIGS. 9 and 10, a plurality of openings 101 are formed to penetrate an outer circumferential surface of an internal electrode 104. For example, punching is performed on the outer circumferential surface of the internal electrode 104 to form a plurality of circular or rectangular holes (openings 101). For example, the plurality of openings 101 are preferably formed in a region of 20% or more of an outer circumferential area of the internal electrode 104. The rest of the structure is identical to those of FIGS. 2 and 3.

In the examples of FIGS. 9 and 10, the case where a radio-frequency (RF) voltage is applied to the internal electrode 104 with a pipe body 102 as a ground electrode connected to a ground is shown. Specifically, an introduction terminal 111 is introduced into the pipe body 102 from an introduction terminal port 105 connected to an outer circumferential surface of the pipe body 102 and the introduction terminal 111 is connected to the internal electrode 104. The plasma generation circuit 106 applies a radio-frequency (RF) voltage to the internal electrode 104 via the introduction terminal 111 with the pipe body 102 as the ground electrode connected to the ground, thereby applying the radio-frequency electric field between the internal electrode 104 and the pipe body 102 (ground electrode). As a result, plasma (CCP) is generated in a space between the internal electrode 104 and the pipe body 102. In the fourth embodiment, hollow cathode discharge plasma is generated in the plurality of openings 101 of the internal electrode 104. The hollow cathode discharge plasma diffuses from the plurality of openings 101 to the inside of the internal electrode 104. As a result, a plasma space can be expanded. Alternatively, even when a hollow cathode effect does not occur, the plasma leaks into the internal electrode 104 from the plurality of openings 101, so that the plasma space can be expanded. F radicals based on the plasma are generated by using the rest of the cleaning gas such as NF3 gas supplied from the upstream side by the cleaning step described above. Then, the products deposited in the pipe body 102 are removed by the F radicals. By expanding the plasma space, cleaning efficiency in the exhaust pipe 152 can be further improved.

As described above, according to the fourth embodiment, the plurality of holes are formed in the internal electrode 104, so that the plasma space can be expanded.

### Fifth Embodiment

In a fifth embodiment, a configuration for further expanding a plasma space than the third embodiment will be described. In addition, points not specifically described below are the same as those of the third embodiment.

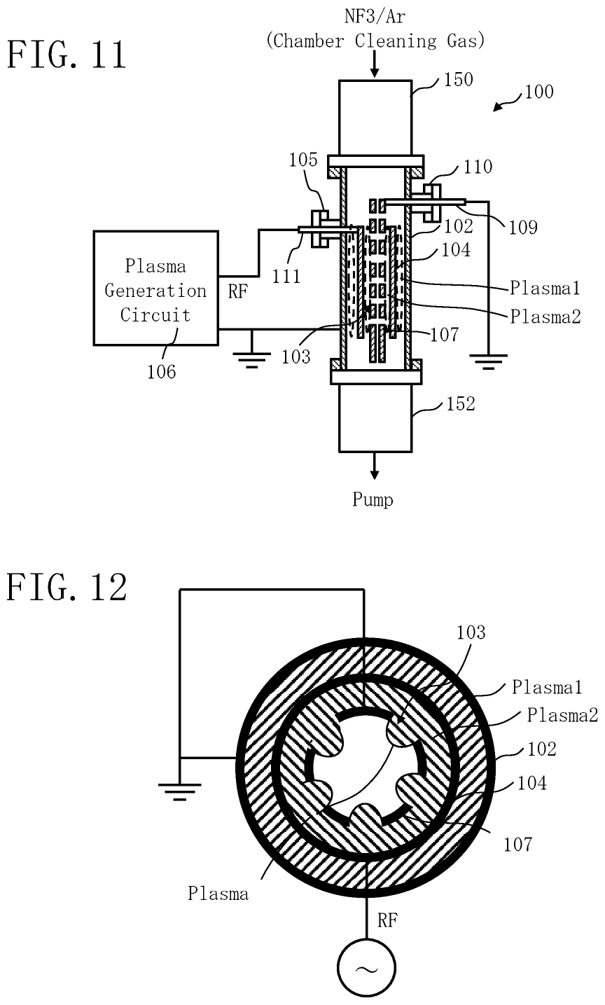

FIG. 11 is a cross-sectional view of an example of an exhaust pipe device in a fifth embodiment when viewed from a front direction. FIG. 12 is a cross-sectional view of an example of the exhaust pipe device in the fifth embodiment when viewed from a top surface direction. In FIGS. 11 and 12, a plurality of openings 103 are formed to penetrate an outer circumferential surface of an internal electrode 107. For example, punching is performed on the outer circumferential surface of the internal electrode 107 to form a plurality of circular or rectangular holes (openings 103). A rear end position of the internal electrode 107 is set to the downstream side of a rear end position of an internal electrode 104. In other words, the internal electrode 107 is formed longer than the internal electrode 104 in a direction where gas is discharged. The rest of the structure is identical to those of FIGS. 7 and 8.

In the examples of FIGS. 11 and 12, a radio-frequency (RF) voltage is applied to the internal electrode 104 with a pipe body 102 as a ground electrode (first ground electrode) connected to a ground and the internal electrode 107 as a ground electrode (second ground electrode) connected to the ground. Specifically, an introduction terminal 111 is introduced into the pipe body 102 from the introduction terminal port 105 and the introduction terminal 111 is connected to the internal electrode 104. Further, the introduction terminal 109 is introduced into the pipe body 102 from the introduction terminal port 110 and the introduction terminal 109 is connected to the internal electrode 107. In addition, the introduction terminal 109 is connected to the ground. A plasma generation circuit 106 applies a radio-frequency (RF) voltage to the internal electrode 104 via the introduction terminal 111 with both the pipe body 102 and the internal electrode 107 as the ground electrodes connected to the ground, thereby applying the radio-frequency electric field between the internal electrode 104 and the pipe body 102 (first ground electrode) and between the internal electrode 104 and the internal electrode 107 (second ground electrode). As a result, first plasma (CCP) is generated in a space between the internal electrode 104 and the pipe body 102 and second plasma (CCP) is generated in a space between the internal electrode 104 and the internal electrode 107. In the fifth embodiment, hollow cathode discharge plasma is further generated in the plurality of openings 103 of the internal electrode 107. The hollow cathode discharge plasma diffuses from the plurality of openings 103 to the inside of the internal electrode 107. As a result, a plasma space can be expanded. Alternatively, even when a hollow cathode effect does not occur, the plasma leaks into the internal electrode 107 from the plurality of openings 103, so that the plasma space can be expanded. F radicals based on the plasma are generated by using the rest of the cleaning gas such as NF3 gas supplied from the upstream side by the cleaning step described above. Then, the products deposited in the pipe body 102 are removed by the F radicals. By expanding the plasma space, cleaning efficiency in the exhaust pipe 152 can be further improved.

By lengthening the internal electrode 107, a surface area of the internal electrode 107 can be increased and a large amount of products can be trapped by the internal electrode 107 in a film forming step. The trapped products can be removed by the F radicals in the cleaning step.

As described above, according to the fifth embodiment, the plurality of holes are formed in the internal electrode 107, so that the plasma space can be further expanded to the center side of the pipe body 102.

### Sixth Embodiment

In a sixth embodiment, a configuration of removing products passively deposited internally by an exhaust pipe device 100 are removed and removing the deposited products after actively depositing the products are removed will be described. In addition, points not specifically described below are the same as those of the first embodiment.

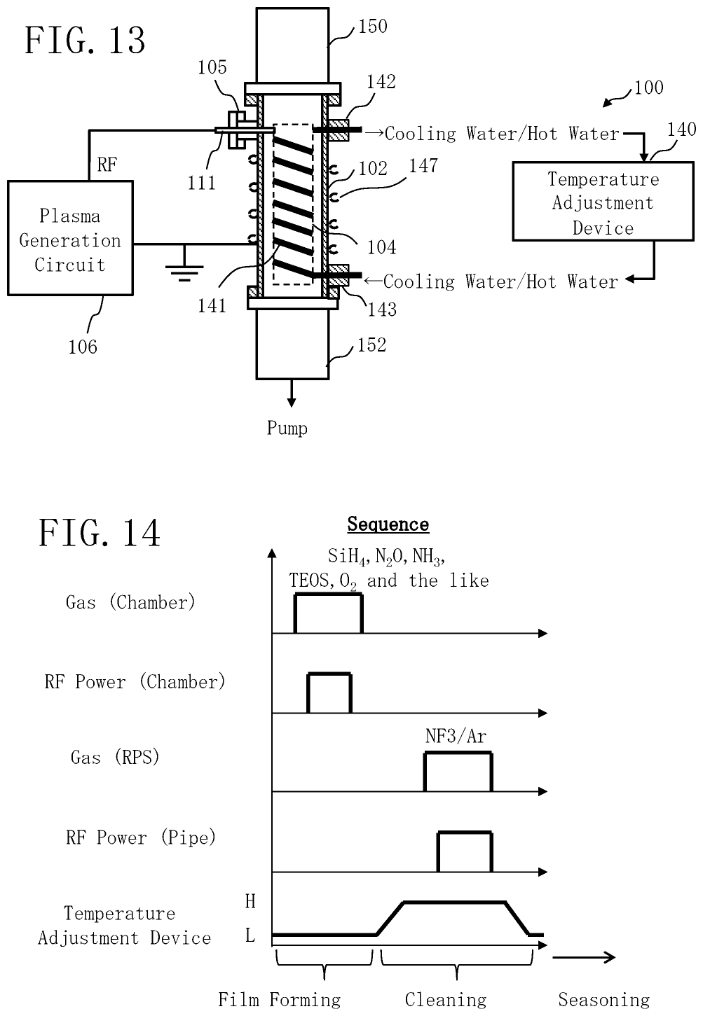

FIG. 13 is a cross-sectional view of an example of an exhaust pipe device in a sixth embodiment when viewed from a front direction. In FIG. 13, the exhaust pipe device 100 in the sixth embodiment functions as an example of a cleaning device. The cleaning device removes the deposited products after actively depositing the products. Specifically, a heat exchanging tube 141 is disposed to extend along an outer circumferential surface of an internal electrode 104. In the example of FIG. 13, the case where the heat exchanging tube 141 is disposed to spirally extend along the outer circumferential surface of the internal electrode 104 while contacting the outer circumferential surface of the internal electrode 104 is shown. Further, tube introduction ports 142 and 143 are disposed on an outer circumferential surface of a pipe body 102. In the example of FIG. 13, the tube introduction port 142 is disposed in an upper portion of the outer circumferential surface of the pipe body 102 and the tube introduction port 143 is disposed in a lower portion of the outer circumferential surface. One end side of the heat exchanging tube 141 goes out from the inside of the pipe body 102 through the tube introduction port 142 and is connected to a temperature adjustment device (temperature control device) 140. The other end side of the heat exchanging tube 141 goes out from the inside of the pipe body 102 through the tube introduction port 143 and is connected to the temperature adjustment device (temperature control device) 140. As the heat exchanging tube 141, for example, a stainless tube is preferably used. For example, it is preferable to use a ¼-inch SUS tube, a ⅜-inch SUS tube, or the like. The heat exchanging tube 141 may have other sizes. A material of the heat exchanging tube 141 may be, for example, the same material as that of the internal electrode 104. For example, an SUS304 material is used. From the viewpoint of corrosion resistance, the material of the heat exchanging tube 141 is more preferably an SUS316 material. The rest of the structure is identical to those of FIGS. 2 and 3.

FIG. 14 is a time chart showing an example of a film forming process sequence in the sixth embodiment. In a film forming process cycle, under the same conditions as those in formation of a film on a substrate 204, a seasoning step of forming a predetermined amount of film on an inner wall of a film forming chamber 202 in the absence of a substrate 204, a film forming step of actually forming a film on the substrate 204, and a cleaning step of removing products deposited by the film formation are repeatedly performed. In the example of FIG. 14, an example of a process sequence in the film forming step and the cleaning step is shown. In the example of FIG. 14, the case where a plasma CVD method is performed is shown. In the sixth embodiment, the temperature adjustment device 140 switches between cooling (L) and heating (H) in synchronization with the process sequence using the film forming chamber 202. In the example of FIG. 13, the temperature adjustment device 140 (temperature adjustment mechanism) in the exhaust pipe device 100 performs cooling and heating on the internal electrode 104.

In the film forming step, a desired combination of raw material gases among SiH₄, nitrogen monoxide (N₂O), ammonia (NH₃), TEOS, and oxygen (O₂) are supplied to the inside of the film forming chamber 202 and plasma is generated in the film forming chamber 202. As a result, a desired film is formed on the substrate 204 in the film forming chamber 202. During the film forming step of forming the film on the substrate 204 in the film forming chamber 202, the temperature adjustment device 140 causes cooling water to flow into the heat exchanging tube 141 and cools the internal electrode 104. The cooling water flows from the downstream side to the upstream side along a direction where the gas is discharged. As a result, a heat exchange can be accelerated. By the cooling, the internal electrode 104 functions as a trap mechanism and actively and positively deposits the products on the surface of the internal electrode 104. During the cooling of the internal electrode 104, a plasma generation circuit 106 does not apply a radio-frequency voltage and does not generate plasma in a space between the internal electrode 104 and the pipe body 102. As a result, trap efficiency of the products can be improved.

In the cleaning step, first, the temperature adjustment device 140 switches the cooling water to hot water. Then, an RPS device 300 supplies cleaning gas such as NF₃ gas or purge gas such as Ar gas to generate fluorine (F) radicals by the plasma and supplies (diffuses) the F radicals to the inside of the film forming chamber 202 and the side of the exhaust pipe 150 to clean the deposited products. During the cleaning step, the temperature adjustment device 140 causes the hot water instead of the cooling water to flow into the heat exchanging tube 141 and heats the internal electrode 104. The hot water flows from the downstream side to the upstream side along the direction where the gas is discharged. As a result, a heat exchange can be accelerated. At the same time, the plasma generation circuit 106 applies a radio-frequency (RF) voltage to the internal electrode 104 via an introduction terminal 111 with the pipe body 102 as a ground electrode connected to a ground, thereby applying the radio-frequency electric field between the internal electrode 104 and the pipe body 102 (ground electrode). As a result, plasma (CCP) is generated in a space between the internal electrode 104 and the pipe body 102. F radicals based on the plasma are generated by using the rest of the cleaning gas such as NF3 gas supplied from the upstream side by the cleaning step described above. The products positively deposited in the pipe body 102 are removed by the F radicals. By heating the internal electrode 104 on which the products are deposited, an etching rate by the F radicals can be improved and cleaning efficiency can be increased. For example, SiF₄ generated after decomposition of the deposited products by the F radicals is highly volatile, so that it is discharged by the vacuum pump 400 through the exhaust pipe 152. By actively trapping the products by the internal electrode 104, it is possible to reduce an amount of products entering the vacuum pump 400 of the downstream side. Therefore, the amount of products deposited in the vacuum pump 400 can be reduced. As a result, the risk of stopping the vacuum pump 400 can be reduced.

After the cleaning step ends, the process proceeds to the seasoning step. In the seasoning step, similar to the film forming step, the temperature adjustment device 140 causes the cooling water to flow into the heat exchanging tube 141 to cool the internal electrode 104 and the plasma generation circuit 106 does not apply the radio-frequency voltage and does not generate plasma in the space between the internal electrode 104 and the pipe body 102.

In the example of FIG. 13, the case where the heat exchanging tube 141 is disposed to extend along the outer circumferential surface of the internal electrode 104 is shown. However, the present disclosure is not limited thereto. As shown by a dotted line in FIG. 13, a heat exchanging tube 147 may be disposed to extend along the outer circumferential surface of the pipe body 102. The heat exchanging tube 147 may use the same material as that of the heat exchanging tube 141. However, since the heat exchanging tube 147 is located outside the pipe body 102, corrosion resistance performance may be lower than that of the heat exchanging tube 141. For example, it is preferable to use an SUS304 tube. As a result, the temperature adjustment device 140 (temperature adjustment mechanism) performs cooling and heating on the pipe body 102. In this case, an inner wall surface of the pipe body 102 functions as a trap mechanism and can actively and positively deposits the products on an inner wall surface of the pipe body 102. Alternatively, the heat exchanging tubes 141 (147) may be disposed to extend along both the outer circumferential surface of the internal electrode 104 and the outer circumferential surface of the pipe body 102. As a result, the temperature adjustment device 140 (temperature adjustment mechanism) performs cooling and heating on at least one of the internal electrode 104 and the pipe body 102. At least one of the internal electrode 104 and the pipe body 102 functions as a trap mechanism and actively and positively removes the deposited products by the heating and the F radicals based on the plasma.

In the example of FIG. 13, the case where the heat exchanging tube 141 is disposed to extend along the internal electrode 104 to which the radio-frequency voltage is applied is shown. However, the present disclosure is not limited thereto. The heat exchanging tube 141 may be disposed to extend along the internal electrode 104 to be the ground electrode shown in FIG. 5. Further, the heat exchanging tube 141 may be disposed to extend along the internal electrode 107 shown in FIG. 7, instead of or together with the internal electrode 104.

As described above, according to the sixth embodiment, the cleaning efficiency can be increased by adjusting the temperature. Further, since the deposited products are removed after the products are actively and positively deposited, the products deposited on the downstream side can be reduced. Further, the internal electrode 104 and/or the pipe body 102 can be temperature-adjusted and can be automatically cleaned by the radicals based on the plasma, so that maintenance can be performed without detaching.

### Seventh Embodiment

In a seventh embodiment, a configuration for further increasing trap efficiency of products as compared with the sixth embodiment will be described. In addition, points not specifically described below are the same as those of the sixth embodiment.

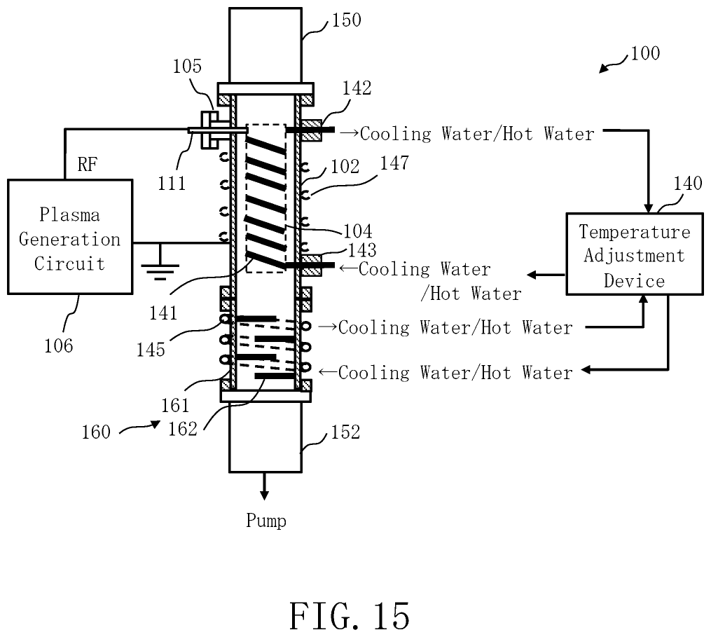

FIG. 15 is a cross-sectional view of an example of an exhaust pipe device in a seventh embodiment when viewed from a front direction; In FIG. 15, an exhaust pipe device 100 further includes a trap mechanism 160. The trap mechanism 160 has a trap pipe 161, a plurality of trap plates 162 disposed in a staggered manner in the trap pipe 161, and a heat exchanging tube 145 disposed to extend along an outer circumferential surface of the trap pipe 161. The trap mechanism 160 is connected to a pipe body 102 on the vacuum pump side (downstream side). For the trap pipe 161, for example, a pipe material made of the same material as that of the pipe body 102 is used. For example, a stainless steel material such as SUS304 is used. However, from the viewpoint of corrosion resistance against cleaning gas, an SUS316 material is more preferably used as the material of the trap pipe 161, similar to the pipe body 102. For the trap pipe 161, for example, a pipe material having the same size as that of the pipe body 102 is used. However, the present disclosure is not limited thereto. The trap pipe 161 may be a pipe having a size larger than that of the pipe body 102. Alternatively, for the trap pipe 161, a pipe having a size smaller than those of the exhaust pipes 150 and 152 may be used. Flanges are disposed at both ends of the trap pipe 161, one end of the trap pipe 161 is connected to the pipe body 102 on which a flange of the same size is disposed, and the other end thereof is connected to an exhaust pipe 152 on which a flange of the same size is disposed.

The plurality of trap plates 162 are formed of a plate-like metal or the like. For example, a stainless steel material such as SUS304 is used. However, from the viewpoint of corrosion resistance against the cleaning gas, an SUS316 material is more preferably used as a material of the trap plate 162, similar to the pipe body 102. For example, the trap plate 162 is fixed to an inner wall of the trap pipe 161 in a cantilever manner so that a flow path of the gas flowing into the trap pipe 161 meanders. As a result, it is possible to increase a contact area of the gas flowing into the trap pipe 161 with respect to the trap plate 162. From the viewpoint of corrosion resistance against the cleaning gas or the like, the inner wall surface of the trap pipe 161 and/or each trap plate 162 is preferably coated with a ceramic material, similar to the pipe body 102.

In the example of FIG. 15, the case where the heat exchanging tube 145 is disposed to spirally creep over the outer circumferential surface of the trap pipe 161 while contacting the outer circumferential surface of the trap pipe 161 is shown. Both ends of the heat exchanging tube 145 are connected to a temperature adjustment device 140. As the heat exchanging tube 145, for example, a stainless tube is preferably used. For example, it is preferable to use a ¼-inch SUS tube, a ⅜-inch SUS tube, or the like. The heat exchanging tube 145 may have other sizes. As a material of the heat exchanging tube 145, for example, an SUS304 material is used. The rest of the structure is identical to that of FIG. 13.

The trap mechanism 160 traps products passing through the inside of the pipe body 102. The temperature adjustment device 140 performs cooling and heating on at least one of an internal electrode 104, the pipe body 102, and the trap mechanism 160. Similar to the sixth embodiment, the temperature adjustment device 140 switches between cooling and heating in synchronization with a process sequence using a film forming chamber 202. Hereinafter, the case where the trap mechanism 160 is cooled and heated will be described. The same is applied to the case where the internal electrode 104 and the pipe body 102 are cooled and heated.

During a film forming step of forming a film on a substrate 204 in the film forming chamber 202, the temperature adjustment device 140 causes cooling water to flow into the heat exchanging tube 145 and cools the trap mechanism 160 (in this case, the trap pipe 161). The cooling water flows from the downstream side to the upstream side along a direction where the gas is discharged. As a result, a heat exchange can be accelerated. By the cooling, the trap mechanism 160 actively and positively deposits the products on the inside of the trap mechanism 160, for example, the surfaces of the plurality of trap plates 162 and the inner wall surface of the trap pipe 161. During the cooling of the trap pipe 161, a plasma generation circuit 106 does not apply a radio-frequency voltage and does not generate plasma in a space between the internal electrode 104 and the pipe body 102. As a result, trap efficiency can be improved.

During a cleaning step, the temperature adjustment device 140 causes hot water instead of the cooling water to flow into the heat exchanging tube 145 and heats the trap pipe 161. The hot water flows from the downstream side to the upstream side along the direction where the gas is discharged. As a result, a heat exchange can be accelerated. At the same time, the plasma generation circuit 106 applies a radio-frequency (RF) voltage to the internal electrode 104 via an introduction terminal 111 with the pipe body 102 as a ground electrode connected to a ground, thereby applying the radio-frequency electric field between the internal electrode 104 and the pipe body 102 (ground electrode). As a result, plasma (CCP) is generated in a space between the internal electrode 104 and the pipe body 102. F radicals based on the plasma are generated by using the rest of the cleaning gas such as NF3 gas supplied from the upstream side by the cleaning step described above. The F radicals diffuses from the pipe body 102 to the side of the trap mechanism 160 and the products positively deposited on the surfaces of the plurality of trap plates 162 and the inner wall surface of the trap pipe 161 are removed by the F radicals. By heating the trap pipe 161 where the products is deposited, heat is also transferred to the plurality of trap plates 162 and the plurality of trap plates 162 are also heated. By the heating of the trap mechanism 160, an etching rate by the F radicals can be improved and cleaning efficiency can be increased. For example, SiF₄ generated after decomposition of the deposited products by the F radicals is highly volatile, so that it is discharged by the vacuum pump 400 through the exhaust pipe 152. In the seventh embodiment, by actively trapping the products by the trap mechanism 160, it is possible to reduce an amount of products entering the vacuum pump 400 of the downstream side. Therefore, the amount of products deposited in the vacuum pump 400 can be reduced. As a result, the risk of stopping the vacuum pump 400 can be reduced.

In the example of FIG. 15, the configuration where the products are trapped in two stages of the internal electrode 104 and the trap mechanism 160 is shown. However, a configuration where the products are trapped by only the trap mechanism 160 may be adopted.

As described above, according to the seventh embodiment, the trap mechanism 160 is further provided, so that it is possible to reduce the products deposited on the downstream side. In addition, since the temperature of the trap mechanism 160 can be adjusted and the radicals are supplied from the pipe body 102 directly above the trap mechanism 160 to the trap mechanism 160, automatic cleaning can be performed and maintenance can be performed without detaching.

### Eighth Embodiment

In an eighth embodiment, a configuration capable of adjusting a cleaning rate will be described. In addition, points not specifically described below are the same as those of the first embodiment.

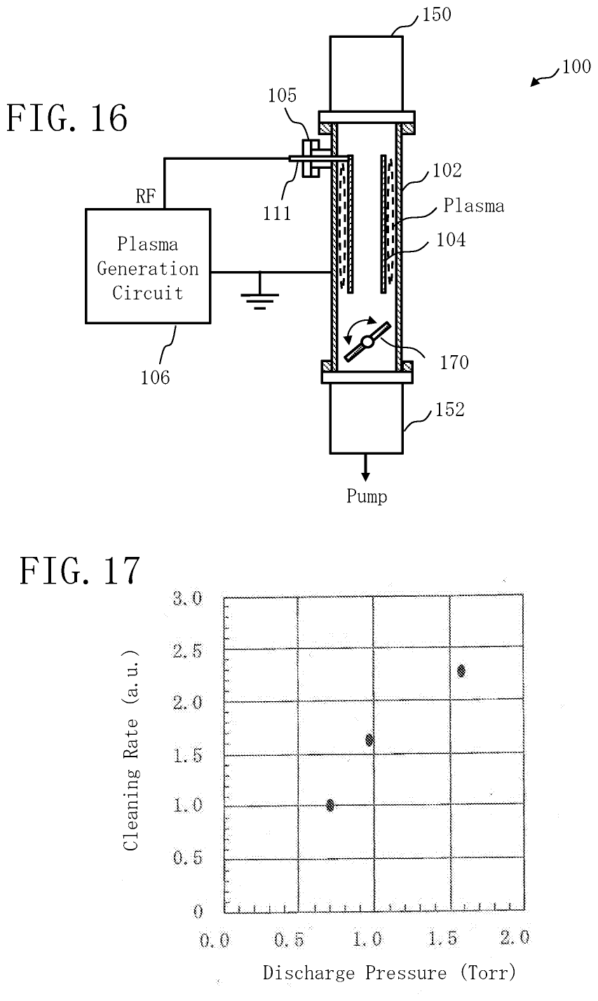

FIG. 16 is a cross-sectional view of an example of an exhaust pipe device in an eighth embodiment when viewed from a front direction. In FIG. 16, an exhaust pipe device 100 further includes a pressure control valve 170. The pressure control valve 170 (pressure adjustment mechanism) is disposed in a pipe body 102 on the vacuum pump side (downstream side of the internal electrode 104). The pressure control valve 170 is disposed in the vicinity of an outlet of the pipe body 102. A conductance in the vicinity of the outlet of the pipe body 102 is controlled to adjust a pressure inside the pipe body 102. The rest of the structure is identical to those of FIGS. 2 and 3.

During a film forming step of forming a film on a substrate 204 in a film forming chamber 202, an opening of the pressure control valve 170 is fully opened, the conductance is increased, and exhaust performance is improved. As a result, it is possible to reduce an influence on a pressure in the film forming chamber 202 in the film forming step.

Then, during a cleaning step, plasma (CCP) is generated in a space between an internal electrode 104 and the pipe body 102 and F radicals based on the plasma are generated by using the rest of cleaning gas such as NF₃ gas. Products deposited in the pipe body 102 are removed by the F radicals. In this case, the opening of the pressure control valve 170 is decreased, the conductance is decreased, and the pressure inside the pipe body 102 is increased. As a result, a cleaning rate in the pipe body 102 can be improved.

FIG. 17 is a diagram showing an example of a relation between a cleaning rate and a discharge pressure in the eighth embodiment; In FIG. 17, a vertical axis shows the cleaning rate and a horizontal axis shows the discharge pressure (torr). As shown in FIG. 17, it is found that the cleaning rate generally increases when the discharge voltage increases.

As described above, according to the eighth embodiment, the cleaning rate can be improved by further including the pressure adjustment mechanism in the pipe body 102.

### Ninth Embodiment

In a ninth embodiment, a configuration capable of adjusting a cleaning rate by a method different from that of the eighth embodiment will be described. In addition, points not specifically described below are the same as those of the first embodiment.

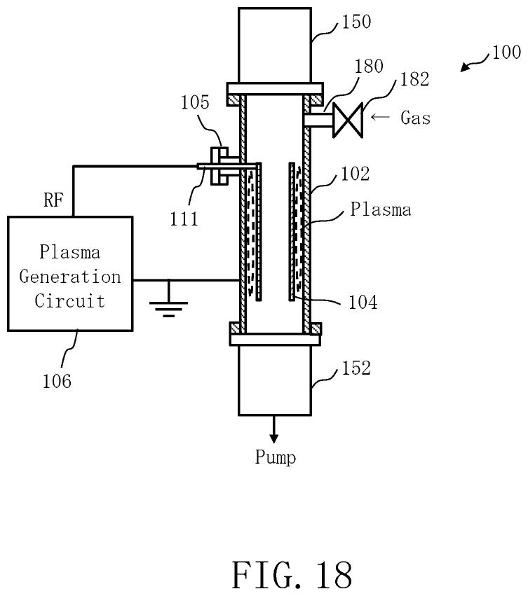

FIG. 18 is a cross-sectional view of an example of an exhaust pipe device in a ninth embodiment when viewed from a front direction. In FIG. 18, an exhaust pipe device 100 further includes a gas introduction port 180. In the example of FIG. 18, the gas introduction port 180 is disposed on the upstream side of an outer circumferential surface of a pipe body 102. The gas introduction port 180 is disposed closer to the side of a film forming chamber 202 (the upstream side) than an internal electrode 104. In addition, a valve 182 is disposed in the gas introduction port 180. By controlling whether or not gas is introduced from the gas introduction port 180 by opening and closing of the valve 182 (another example of a pressure adjustment mechanism), a pressure inside the pipe body 102 is adjusted. The rest of the structure is identical to those of FIGS. 2 and 3.

During a film forming step of forming a film on a substrate 204 in a film forming chamber 202, the valve 182 is closed. If an influence on the pressure inside the film forming chamber 202 in the film forming step can be ignored, the valve 182 may be opened to supply gas.

Then, during a cleaning step, plasma ((capacitively coupled plasma: CCP) is generated in a space between an internal electrode 104 and the pipe body 102 and F radicals based on the plasma are generated. Products deposited in the pipe body 102 are removed by the F radicals. In this case, the valve 182 is opened and the gas is introduced into the pipe body 102 from the gas introduction port 180. Further, the gas introduction port 180 supplies the gas to the inside of the pipe body 102 from the upstream side of the internal electrode 104. It is preferable to use at least one of rare gas, O₂ gas, nitrogen (N₂) gas, NF₃ gas, and perfluorocarbon (PFC) gas as the gas to be introduced. By supplying the gas to the inside of the pipe body 102 from the upstream side of the internal electrode 104, the pressure inside the pipe body 102 can be increased without affecting cleaning performance of the film forming chamber 202 and the cleaning rate in the pipe body 102 can be improved. Furthermore, other effects are also exerted depending on the type of gas to be introduced.

For example, when NF₃ gas is supplied, it is possible to increase the efficiency of re-dissociating deposited products such as SiO₂, as compared with the case where F radicals based on plasma are generated by using NF₃ gas of the rest of the cleaning gas. If the NF₃ gas is supplied as new gas, it is possible to accelerate re-dissociation of the deposited products such as SiO₂. When the NF₃ gas is supplied, it is preferable to introduce the NF₃ gas together with the rare gas such as the Ar gas for adjusting the pressure inside the pipe body 102.

For example, when the O₂ gas is supplied, ignitability to discharge can be increased and a discharge margin can be improved. When the product to be deposited is carbon (C), a radical reaction with C can be generated, which is particularly effective. When the O₂ gas is supplied, it is preferable to introduce the O₂ gas together with the N₂ gas for adjusting the pressure inside the pipe body 102.

As described above, according to the ninth embodiment, the cleaning rate and/or the discharge margin can be improved.

### Tenth Embodiment

In a tenth embodiment, a configuration where a dielectric is disposed between electrodes in an exhaust pipe will be described. In addition, points not specifically described below are the same as those of the first embodiment.

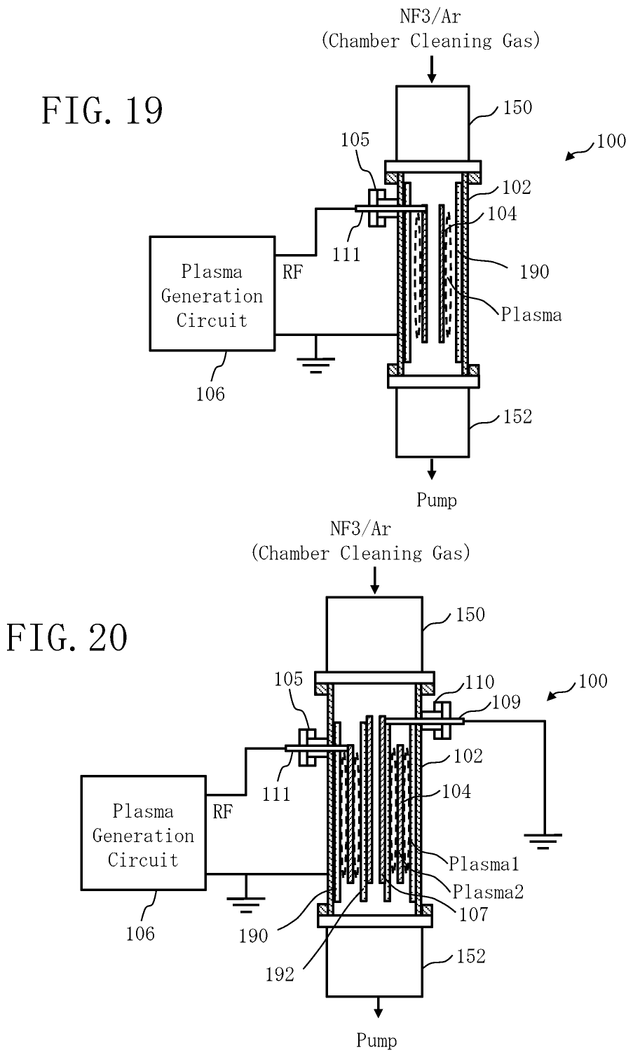

FIG. 19 is a cross-sectional view of an example of an exhaust pipe device in a tenth embodiment when viewed from a front direction. FIG. 19 is the same as FIG. 2 except that a dielectric 190 is disposed along an inner circumferential surface of a pipe body 102 functioning as a ground electrode. The dielectric 190 may be disposed between the pipe body 102 functioning as the ground electrode and an internal electrode 104 to which a radio-frequency (RF) voltage is applied. For example, the dielectric 190 is preferably disposed along an outer circumferential surface of the internal electrode 104. Further, the dielectric 190 may not contact the pipe body 102 and the internal electrode 104. The dielectric 190 is formed in the same type of shape as that of the pipe body 102. In the example of FIG. 19, for the pipe body 102 having a circular cylindrical cross-section, the dielectric 190 having the same type of circular cylindrical cross-section is used. In addition, for the pipe body 102 having a rectangular cylindrical cross-section, the dielectric 190 having the same type of rectangular cylindrical cross-section may be used. The dielectric 190 is preferably formed to have the same length as that of the internal electrode 104 or to be longer than the internal electrode 104 in a vertical direction of a plane of paper of FIG. 19. As a result, it is possible to exclude a region where there is no dielectric 190 between electrodes of the pipe body 102 and the internal electrode 104. The dielectric 190 may be made of a material having a dielectric constant larger than that of air. For example, quartz, Al₂O₃, Y₂O₃, HfO₂, ZrO₂, MgO, or AlN is preferably used as the material of the dielectric 190. A thickness of the dielectric 190 may be appropriately set as long as it does not disturb exhaust performance.

In the example of FIG. 19, similar to the first embodiment, the case where a radio-frequency (RF) voltage is applied to the internal electrode 104 with the pipe body 102 as the ground electrode connected to a ground is shown. Specifically, an introduction terminal 111 (an example of a radio-frequency introduction terminal) is introduced into the pipe body 102 from an introduction terminal port 105 connected to an outer circumferential surface of the pipe body 102 and the introduction terminal 111 is connected to the internal electrode 104. The plasma generation circuit 106 applies a radio-frequency (RF) voltage to the internal electrode 104 via the introduction terminal 111 with the pipe body 102 as the ground electrode connected to the ground, thereby applying the radio-frequency electric field between the internal electrode 104 and the pipe body 102 (ground electrode). As a result, the plasma (capacitively coupled plasma: CCP) is generated in the space between the internal electrode 104 and the pipe body 102.

Here, a distance between the electrodes of the pipe body 102 and the internal electrode 104 may not become uniform due to a manufacturing error or a placement error. In that case, plasma such as arc discharge can be generated at a local position. By disposing the dielectric 190 between the electrodes of the pipe body 102 and the internal electrode 104, charges are accumulated in the dielectric 190 to cause dielectric barrier discharge, so that the electric field is canceled at the local position where the arc discharge or the like tends to occur Therefore, the electric field between the electrodes is averaged and uniform plasma can be generated. As a result, a discharge region can be expanded. By expanding the discharge region, high cleaning performance can be exerted in the exhaust pipe 152.

### Eleventh Embodiment

In an eleventh embodiment, another configuration where a dielectric is disposed between electrodes in an exhaust pipe will be described. In addition, points not specifically described below are the same as those of the third embodiment.

FIG. 20 is a cross-sectional view of an example of an exhaust pipe device in an eleventh embodiment when viewed from a front direction. FIG. 20 is the same as FIG. 7 except that a dielectric 190 is disposed along an inner circumferential surface of a pipe body 102 functioning as a ground electrode and a dielectric 192 is disposed along an outer circumferential surface of another internal electrode 107 inside an internal electrode 104. The dielectric 190 may be disposed between the pipe body 102 functioning as the ground electrode and an internal electrode 104 to which a radio-frequency (RF) voltage is applied. For example, the dielectric 190 is preferably disposed along an outer circumferential surface of the internal electrode 104. Further, the dielectric 190 may not contact the pipe body 102 and the internal electrode 104. The dielectric 190 is formed in the same type of shape as that of the pipe body 102. In the example of FIG. 19, for the pipe body 102 having a circular cylindrical cross-section, the dielectric 190 having the same type of circular cylindrical cross-section is used. In addition, for the pipe body 102 having a rectangular cylindrical cross-section, the dielectric 190 having the same type of rectangular cylindrical cross-section may be used.

Likewise, the dielectric 192 may be disposed between the internal electrode 107 functioning as the ground electrode and the internal electrode 104 to which the radio-frequency (RF) voltage is applied. For example, the dielectric 192 is preferably disposed along an inner circumferential surface of the internal electrode 104. Further, the dielectric 192 may not contact the internal electrode 104 and the internal electrode 107. The dielectric 192 is formed in the same type of shape as that of the internal electrode 104. In the example of FIG. 20, for the internal electrode 104 having a circular cylindrical cross-section, the dielectric 192 having the same type of circular cylindrical cross-section is used. In addition, for the internal electrode 104 having a rectangular cylindrical cross-section, the dielectric 192 having the same type of rectangular cylindrical cross-section may be used.

The dielectrics 190 and 192 are preferably formed to have the same length as that of the internal electrode 104 or to be longer than the internal electrode 104 in a vertical direction of a plane of paper of FIG. 20. As a result, it is possible to exclude a region where there is no dielectric 190 between electrodes of the pipe body 102 and the internal electrode 104. Likewise, it is possible to exclude a region where there is no dielectric 192 between electrodes of the internal electrode 104 and the internal electrode 107. The dielectrics 190 and 192 may be made of a material having a dielectric constant larger than that of air. For example, quartz, Al₂O₃, Y₂O₃, HfO₂, ZrO₂, MgO, or AlN is preferably used as the materials of the dielectrics 190 and 192. A thickness of each of the dielectrics 190 and 192 may be appropriately set as long as it does not disturb exhaust performance.

In the example of FIG. 20, the case where a radio-frequency (RF) voltage is applied to the internal electrode 104 with the pipe body 102 as a ground electrode (first ground electrode) connected to a ground and the internal electrode 107 as a ground electrode (second ground electrode) connected to the ground is shown. Specifically, an introduction terminal 111 is introduced into the pipe body 102 from the introduction terminal port 105 and the introduction terminal 111 is connected to the internal electrode 104. Further, the introduction terminal 109 is introduced into the pipe body 102 from the introduction terminal port 110 and the introduction terminal 109 is connected to the internal electrode 107. In addition, the introduction terminal 109 is connected to the ground. A plasma generation circuit 106 applies a radio-frequency (RF) voltage to the internal electrode 104 via the introduction terminal 111 with both the pipe body 102 and the internal electrode 107 as the ground electrodes connected to the ground, thereby applying the radio-frequency electric field between the internal electrode 104 and the pipe body 102 (first ground electrode) and between the internal electrode 104 and the internal electrode 107 (second ground electrode). As a result, first plasma (capacitively coupled plasma: CCP) is generated in the space between the internal electrode 104 and the pipe body 102 and second plasma (CCP) is generated in the space between the internal electrode 104 and the internal electrode 107.

Here, similar to the tenth embodiment, a distance between electrodes of the pipe body 102 and the internal electrode 104 and/or a distance between electrodes of the internal electrode 104 and the internal electrode 107 may not become uniform due to a manufacturing error or a placement error. In that case, plasma such as arc discharge can be generated at a local position between a pair of electrodes. By disposing the dielectric 190 between the electrodes of the pipe body 102 and the internal electrode 104, charges are accumulated in the entire dielectric 190 and uniform plasma can be generated. Likewise, by disposing the dielectric 192 between the electrodes of the internal electrode 104 and the internal electrode 107, charges are accumulated in the entire dielectric 192 and uniform plasma can be generated. As a result, a discharge region can be expanded. By expanding the discharge region, high cleaning performance can be exerted in the exhaust pipe 152.

### Twelfth Embodiment

In the tenth embodiment, a configuration in which a dielectric is added to expand a discharge region has been described. However, in a twelfth embodiment, an improved configuration of the above configuration will be described. In addition, points not specifically described below are the same as those of the tenth embodiment.

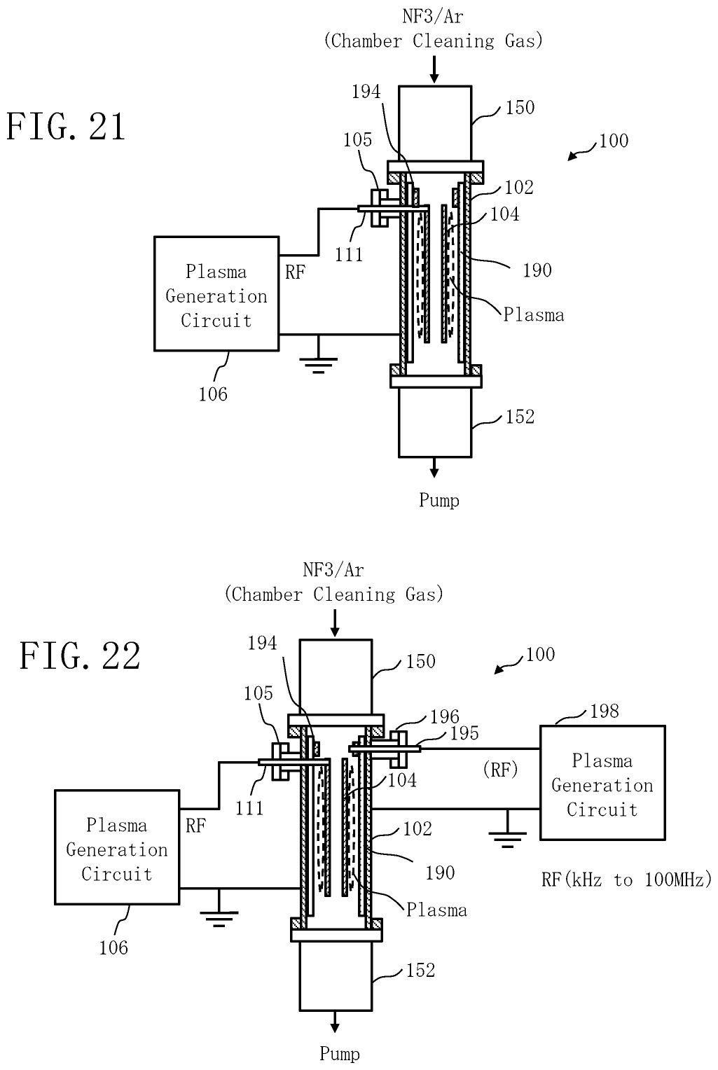

FIG. 21 is a cross-sectional view of an example of an exhaust pipe device in a twelfth embodiment when viewed from a front direction. FIG. 21 is the same as FIG. 19 except that an ignition electrode 194 is disposed near an end of a dielectric 190. In the example of FIG. 21, the ignition electrode 194 is disposed on an inner circumferential surface of the dielectric 190. In addition, most of the ignition electrode 194 is preferably disposed at a position deviated from a region facing the internal electrode 104 in the inner circumferential surface of the dielectric 190. Further, the ignition electrode 194 is connected to an introduction terminal 111. The ignition electrode 194 uses a conductive material such as a metal. For example, it is preferable to use the same material as that of the internal electrode 104.

In the example of FIG. 21, similar to the tenth embodiment, the case where a radio-frequency (RF) voltage is applied to the internal electrode 104 with a pipe body 102 as a ground electrode connected to a ground is shown. Specifically, an introduction terminal 111 (an example of a radio-frequency introduction terminal) is introduced into the pipe body 102 from an introduction terminal port 105 connected to an outer circumferential surface of the pipe body 102 and the introduction terminal 111 is connected to the internal electrode 104. At the same time, the introduction terminal 111 is connected to the ignition electrode 194. A plasma generation circuit 106 applies a radio-frequency (RF) voltage to the internal electrode 104 via the introduction terminal 111 with the pipe body 102 as the ground electrode connected to the ground and applies the RF voltage to the ignition electrode 194. In other words, in the twelfth embodiment, the radio-frequency (RF) voltage is applied from the single plasma generation circuit 106 (power supply) to the internal electrode 104 to be an electrode for CCP and the ignition electrode 194 for creeping discharge. As a result, the creeping discharge is generated on the dielectric 190 in the vicinity of the ignition electrode 194 before the CCP is generated in the pipe body 102 under a pressure lower than an atmospheric pressure. A discharge start voltage of the CCP is lowered by the creeping discharge and ignitability of the plasma (CCP) generated in the space between the internal electrode 104 to which the radio-frequency voltage is applied and the pipe body 102 (ground electrode) can be improved.

According to the twelfth embodiment, similar to the tenth embodiment, the discharge region can be further expanded by the dielectric 190. By expanding the discharge region, high cleaning performance can be exerted in the exhaust pipe 152.

### Thirteenth Embodiment

In the twelfth embodiment, the case where a radio-frequency (RF) voltage is applied from a single plasma generation circuit 106 (power supply) to an internal electrode 104 to be an electrode for CCP and an ignition electrode 194 for creeping discharge has been described. However, the present disclosure is not limited thereto. In a thirteenth embodiment, a configuration in which the radio-frequency voltage is applied from separate power supplies to the internal electrode 104 and the ignition electrode 194 for the creeping discharge will be described. In addition, points not specifically described below are the same as those of the twelfth embodiment.

FIG. 22 is a cross-sectional view of an example of an exhaust pipe device in a thirteenth embodiment when viewed from a front direction. FIG. 22 is the same as FIG. 21 except that the ignition electrode 194 is disposed not to contact an introduction terminal 111, an introduction terminal port 196 is connected to an outer circumferential surface of a pipe body 102, an introduction terminal 195 is introduced into the pipe body 102 from the introduction terminal port 196, the introduction terminal 195 is connected to the ignition electrode 194 via a dielectric 190, and a plasma generation circuit 198 to apply a radio-frequency electric field to the introduction terminal 195 is added. In the example of FIG. 22, a disposition position of the ignition electrode 194 is set to the upstream side of a front end position of the internal electrode 104. The introduction terminal 195 is introduced from the introduction terminal port 196 disposed on the upstream side of an introduction terminal port 105 without interfering with a region between electrodes of the pipe body 102 and the internal electrode 104 and is connected to the ignition electrode 194.

In the example of FIG. 22, similar to the twelfth embodiment, the plasma generation circuit 106 applies a radio-frequency (RF) voltage to the internal electrode 104 via the introduction terminal 111 with the pipe body 102 as a ground electrode connected to a ground, thereby applying the radio-frequency electric field between the internal electrode 104 and the pipe body 102. Independently of the application of the radio-frequency electric field by the plasma generation circuit 106, the plasma generation circuit 198 applies the radio-frequency voltage to the ignition electrode 194 on the dielectric 190 via the introduction terminal 195 with the pipe body 102 as a ground electrode connected to the ground, thereby applying the radio-frequency electric field between the ignition electrode 194 and the pipe body 102. As a result, the creeping discharge is generated on the dielectric 190 in the vicinity of the ignition electrode 194 before the CCP in the pipe body 102 under a pressure lower than an atmospheric pressure. A discharge start voltage of the plasma CCP due to the application of the radio-frequency electric field by the plasma generation circuit 106 is lowered by the creeping discharge and ignitability of the plasma CCP generated in a space between the internal electrode 104 to which the radio-frequency voltage is applied and the pipe body 102 (ground electrode) can be improved. By disposing the plasma generation circuit 198 separately from the plasma generation circuit 106 for creeping discharge, the ignitability can be improved without affecting the plasma CCP in a steady state, when it is difficult to start the discharge by only the main plasma generation circuit 106 under conditions such as a low pressure. Furthermore, the plasma generation circuit 198 may generate the creeping discharge on the dielectric 190 near the ignition electrode 194 and may prepare a small and inexpensive radio-frequency power supply as compared with the plasma generation circuit 106. Therefore, ignitability of the plasma CCP can be improved at low cost.

In the above example, the case where the radio-frequency electric field is applied from the plasma generation circuit 198 to the ignition electrode 194 has been described. However, the present disclosure is not limited thereto. The present disclosure may be applied to the case of applying, from the plasma generation circuit 198 to the ignition electrode 194, an RF electric field of about 1 kHz to several 100 kHz (for example, 400 kHz or less) lower than the radio-frequency (RF) electric field (about 1 to 100 MHz) applied from the plasma generation circuit 106 to the internal electrode 104.

According to the thirteenth embodiment, similar to the tenth embodiment, a discharge region can be further expanded by the dielectric 190. By expanding the discharge region, high cleaning performance can be exerted in the exhaust pipe 152.

### Fourteenth Embodiment

In a fourteenth embodiment, a configuration where an internal electrode 104 functions as both an RF electrode and a creeping discharge electrode will be described. In addition, points not specifically described below are the same as those of the third embodiment.

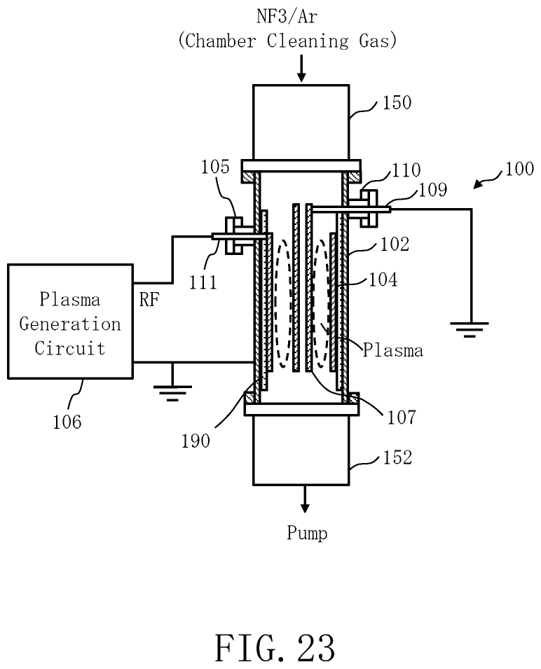

FIG. 23 is a cross-sectional view of an example of an exhaust pipe device in a fourteenth embodiment when viewed from a front direction. FIG. 23 is the same as FIG. 7 except that a dielectric 190 is disposed along an inner circumferential surface of a pipe body 102 functioning as a ground electrode and an internal electrode 104 is disposed on the dielectric 190 along an inner circumferential surface of the dielectric 190. The dielectric 190 is formed in the same type of shape as those of the pipe body 102 and the internal electrode 104. In the example of FIG. 23, for the pipe body 102 and the internal electrode 104 having a circular cylindrical cross-section, the dielectric 190 having the same type of circular cylindrical cross-section is used. In addition, for the pipe body 102 and the internal electrode 104 having a rectangular cylindrical cross-section, the dielectric 190 having the same type of rectangular cylindrical cross-section may be used. In the example of FIG. 23, the dielectric 190 is disposed between the pipe body 102 functioning as the ground electrode and the internal electrode 104 to which a radio-frequency (RF) voltage is applied, without a gap. Therefore, CCP is not generated between the pipe body 102 and the internal electrode 104 and the CCP is generated between the internal electrode 104 and an internal electrode 107.

In the example of FIG. 23, the dielectric 190 is formed so that a front end position of the dielectric 190 is longer on the upstream side and/or the downstream side than a front end position of the internal electrode 104. Similar to the tenth embodiment, the dielectric 190 may be made of a material having a dielectric constant larger than that of air. For example, quartz, Al₂O₃, Y₂O₃, HfO₂, ZrO₂, MgO, or AlN is preferably used as the material of the dielectric 190. A thickness of the dielectric 190 may be appropriately set as long as it does not disturb exhaust performance. By setting the thickness of the dielectric 190 to a value smaller than a distance of a space between the pipe body 102 and the internal electrode 104 in FIG. 7, it is possible to increase a distance of a space between the internal electrode 104 and the internal electrode 107.

In the example of FIG. 23, the case where a radio-frequency (RF) voltage is applied to the internal electrode 104 with the pipe body 102 as a ground electrode (first ground electrode) connected to a ground and the internal electrode 107 as a ground electrode (second ground electrode) connected to the ground is shown. Specifically, an introduction terminal 111 is introduced into the pipe body 102 from the introduction terminal port 105 and the introduction terminal 111 is connected to the internal electrode 104. Further, the introduction terminal 109 is introduced into the pipe body 102 from the introduction terminal port 110 and the introduction terminal 109 is connected to the internal electrode 107. In addition, the introduction terminal 109 is connected to the ground. A plasma generation circuit 106 applies a radio-frequency (RF) voltage to the internal electrode 104 via the introduction terminal 111 with both the pipe body 102 and the internal electrode 107 as the ground electrodes connected to the ground, thereby applying the radio-frequency electric field between the internal electrode 104 and the pipe body 102 (first ground electrode) and between the internal electrode 104 and the internal electrode 107 (second ground electrode). As a result, creeping discharge is generated on the dielectric 190 exposed without being covered by the internal electrode 104 in the vicinity of the internal electrode 104, before plasma (CCP) in the pipe body 102 under a pressure lower than an atmospheric pressure. A discharge start voltage of the CCP is lowered by the creeping discharge and ignitability of the CCP generated in the space between the internal electrode 104 to which the radio-frequency voltage is applied and the internal electrode 107 (ground electrode) can be improved.

F radicals based on the plasma are generated by using the rest of the cleaning gas such as NF3 gas supplied from the upstream side by the cleaning step described above. Then, the products deposited in the pipe body 102 are removed by the F radicals. For example, SiF₄ generated after decomposition of the deposited products by the F radicals is highly volatile, so that it is discharged by the vacuum pump 400 through the exhaust pipe 152. In addition, the products deposited in the vacuum pump 400 are cleaned by the radicals diffusing into the vacuum pump 400, so that it is possible to further reduce an amount of products deposited in the vacuum pump 400.

The embodiments have been described with reference to the specific examples. However, the present disclosure is not limited to these specific examples. Each of the sixth to ninth embodiments may be combined with any one of the second to fifth embodiments instead of the first embodiment. Further, each of the sixth and seventh embodiments may be combined with any one of the eighth and ninth embodiments. Further, the eighth and ninth embodiments may be combined.

Further, all exhaust pipe devices and cleaning devices including the elements of the present disclosure and capable of being appropriately designed and changed by those skilled in the art and methods for fabricating the semiconductor devices are included in the scope of the present disclosure.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods and devices described herein may be made without departing from the spirit of the inventions. The accompanying claims and their equivalents are intended to cover such forms or modifications as would fall within the scope and spirit of the inventions.

1. An exhaust pipe device comprising:
a pipe body;
an internal electrode formed in a pipe shape and disposed in the pipe body; and
a plasma generation circuit configured to generate plasma in the pipe body by using the internal electrode,
wherein the exhaust pipe device is used as a part of an exhaust pipe disposed between a film forming chamber and a vacuum pump for exhausting an inside of the film forming chamber.

2. The device according to claim 1, wherein
a metal electrode is used as the internal electrode and
the plasma generation circuit uses the pipe body as a ground electrode connected to a ground and applies a radio-frequency electric field between the internal electrode and the ground electrode.

3. The device according to claim 1, further comprising:
an external electrode disposed outside the pipe body, wherein
a metal electrode is used as the internal electrode and
the plasma generation circuit uses the internal electrode as a ground electrode connected to a ground and applies a radio-frequency electric field between the internal electrode and the external electrode.

4. The device according to claim 1, wherein the internal electrode is formed in the same type of shape as a shape of the pipe body.

5. The device according to claim 1, wherein the internal electrode is formed in a hollow structure.

6. The device according to claim 1, wherein the internal electrode is formed in a cylindrical shape and a plurality of openings are formed to penetrate an outer circumferential surface of the internal electrode.

7. The device according to claim 2, wherein the pipe body is used as a first ground electrode, the exhaust pipe device further comprising a second ground electrode disposed in the internal electrode and connected to a ground.

8. The device according to claim 7, wherein the second ground electrode is formed longer than the internal electrode in a direction where gas is discharged.

9. The device according to claim 1, wherein a radio-frequency introduction terminal to apply a radio-frequency electric field is connected to a vicinity of an end of the internal electrode located at a side of the film forming chamber.

10. The device according to claim 1, further comprising:
a radio-frequency introduction terminal configured to apply a radio-frequency electric field to the internal electrode;
an introduction terminal port connected to an outer circumferential surface of the pipe body and introducing the radio-frequency introduction terminal into the pipe body;
an insulator disposed in the introduction terminal port and surrounding an outer circumferential surface of the radio-frequency introduction terminal; and
a spacer disposed in the introduction terminal port, formed so that an end of the spacer is located on substantially the same surface as an inner wall surface of the pipe body, and closing a gap between the insulator and an inner wall of the introduction terminal port.

11. The device according to claim 1, further comprising: a gas introduction port configured to introduce gas from a side closer to the film forming chamber than the internal electrode.

12. The device according to claim 11, wherein at least one of rare gas, oxygen gas, nitrogen gas, nitrogen trifluoride gas, and perfluorocarbon (PFC) gas is used as the gas.

13. The device according to claim 1, further comprising:
a pressure adjustment mechanism configured to adjust a pressure inside the pipe body.

14. The device according to claim 13, wherein a pressure control valve is used as the pressure adjustment mechanism.

15. The device according to claim 14, wherein the pressure control valve is disposed at a downstream side of the internal electrode.

16. The device according to claim 1, further comprising:
a trap mechanism connected to the pipe body at a side of the vacuum pump and trapping products passing through an inside of the pipe body; and
a temperature adjustment mechanism configured to cool and heat at least one of the internal electrode, the pipe body, and the trap mechanism.

17. The device according to claim 16, wherein the temperature adjustment mechanism switches between the cooling and the heating in synchronization with a process sequence using the film forming chamber.

18. A cleaning device comprising:
an internal electrode disposed in a pipe body of an exhaust pipe disposed between a film forming chamber and a vacuum pump for exhausting an inside of the film forming chamber;
a plasma generation circuit configured to generate plasma in the pipe body by using the internal electrode; and
a temperature adjustment mechanism configured to cool and heat at least one of the internal electrode and the exhaust pipe.

19. The device according to claim 18, further comprising:
a trap mechanism connected to the pipe body at a side of the vacuum pump and trapping products passing through inside of the pipe body.

20. The device according to claim 18, wherein the temperature adjustment mechanism switches between the cooling and the heating in synchronization with a process sequence using the film forming chamber.
